(19) United States
(12) Patent Application Publication
(10) Pub. No.: US 2022/0078910 A1
(43) Pub. Date: Mar. 10, 2022

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Byeung Kyu PARK, Suwon-si (KR); Ha Il KIM, Suwon-si (KR); Young Man KIM, Suwon-si (KR); Bong Ki SONG, Suwon-si (KR); Eun Hee KIM, Suwon-si (KR); Jong Hoe PARK, Suwon-si (KR); Sun Young CHOI, Suwon-si (KR)

(21) Appl. No.: 17/104,104

(22) Filed: Nov. 25, 2020

(30) Foreign Application Priority Data
Sep. 4, 2020 (KR) 10-2020-0113262

(51) Int. Cl. H05K 1/11; H05K 3/46

(52) U.S. Cl. CPC H05K 1/116; H05K 3/425; H05K 3/4647

(57) ABSTRACT

A printed circuit board includes: a first insulating layer; a first circuit layer disposed on one surface of the first insulating layer; a second insulating layer disposed on the first insulating layer and covering at least a portion of the first circuit layer; a via conductor passing through the second insulating layer and connected to the first circuit layer; a via land connected to the via conductor in an upper portion of the via conductor; and a second circuit layer disposed on the second insulating layer and connected to the via land. The via conductor and the via land have a first interface where the via conductor and the via land are in contact with each other.

### CROSS-REFERENCE TO RELATED APPLICATION(S)

This application claims benefit of priority to Korean Patent Application No. 10-2020-0113262 filed on Sep. 4, 2020 in the Korean Intellectual Property Office, the disclosure of which is incorporated herein by reference in its entirety.

### TECHNICAL FIELD

The present disclosure relates to a printed circuit board, for example, a printed circuit board in which a via conductor and a via land are distinguished.

### BACKGROUND

Since reliability of a via for interlayer connection becomes more important as a printed circuit board is developed to have multiple layers, a method of manufacturing a printed circuit board having improved reliability of the via is required. In addition, even a product to which new technology is applied is required to reduce costs, as compared to existing methods.

### SUMMARY

An aspect of the present disclosure is to provide a printed circuit board having excellent reliability and a matching characteristic of a via.

An aspect of the present disclosure is to provide a printed circuit board having a structure in which an interface is formed between a via conductor and a via land to distinguish the via conductor and the via land.

An aspect of the present disclosure is to provide a printed circuit board manufactured by a manufacturing method excluding a via processing process using a laser and including a via processing process using a dry film.

One of the various solutions proposed through the present disclosure is to implement a structure of a printed circuit board processing a via using a dry film, instead of a laser, to prevent residues of a resin, precisely processing a via to secure a matching characteristic and reliability of the via, and forming an interface between a via conductor and a via land.

For example, according to an aspect of the present disclosure, a printed circuit board includes: a first insulating layer; a first circuit layer disposed on one surface of the first insulating layer; a second insulating layer disposed on the first insulating layer and covering at least a portion of the first circuit layer; a via conductor passing through the second insulating layer and connected to the first circuit layer; a via land connected to the via conductor in an upper portion of the via conductor; and a second circuit layer disposed on the second insulating layer and connected to the via land. The via conductor and the via land have a first interface where the via conductor and the via land are in contact with each other.

For example, according to an aspect of the present disclosure, a printed circuit board includes: a first insulating layer; a first circuit layer disposed on at least portion of one surface of the first insulating layer; a second insulating layer disposed on at least portion of the one surface of the first insulating layer and covering at least a portion of the first circuit layer; a via conductor passing through the second insulating layer and connected to the first circuit layer; a via land connected to the via conductor in an upper portion of the via conductor; and a second circuit layer disposed on the second insulating layer and connected to the via land. The via land and the second circuit layer have a second interface where the via land and the second circuit layer are in contact with each other.

For example, according to an aspect of the present disclosure, a printed circuit board includes: a first insulating layer; a first circuit layer disposed on the first insulating layer and having an opening; a second insulating layer disposed on the first circuit layer and extending in the opening of the first circuit layer to contact the first insulating layer; a via conductor passing through a portion of the second insulating layer disposed on the first circuit layer, and connected to the first circuit layer; and a second circuit layer disposed on the second insulating layer and connected to the via conductor.

For example, according to an aspect of the present disclosure, a method for manufacturing a printed circuit board includes forming a first circuit layer on an insulating layer; after forming the first circuit layer, forming a via conductor extending from the first circuit layer; disposing a dry film with an opening on the first circuit layer such that the via conductor is disposed in the opening in the dry film; and forming a second circuit layer on the dry film.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system.

FIG. 2 is a plan view schematically illustrating an example of an electronic device.

FIG. 3 is a cross-sectional view schematically illustrating a first insulating layer.

FIG. 4 is a cross-sectional view schematically illustrating a structure in which a first metal layer is stacked on one surface of a first insulating layer.

FIG. 5 is a cross-sectional view schematically illustrating a structure in which a first circuit layer is formed by patterning a first metal layer.

FIG. 6 is a cross-sectional view schematically illustrating a structure in which a dry film is stacked on a first circuit layer.

FIG. 7 is a cross-sectional view schematically illustrating a structure in which a via conductor is plated on an exposed region of a first circuit layer.

FIG. 8 is a cross-sectional view schematically illustrating a process of polishing or etching an upper surface of a via conductor and an upper surface of a dry film.

FIG. 9 is a cross-sectional view schematically illustrating a structure off of which a dry film is peeled.

FIG. 10A is a cross-sectional view schematically illustrating a structure in which a first opening is formed on a second insulating layer before stacking.

FIG. 10B is a cross-sectional view schematically illustrating a structure in which a second insulating layer is stacked on a first circuit layer.

FIG. 10C is an enlarged cross-sectional view enlarging and illustrating portion A of FIG. 10B.

FIG. 11A is a cross-sectional view schematically illustrating a structure in which a second opening is formed on a second metal layer before stacking.

FIG. 11B is a cross-sectional view schematically illustrating a structure in which a second metal layer is stacked on a second insulating layer.

FIG. 11C is an enlarged cross-sectional view enlarging and illustrating portion B of FIG. 11B.

FIG. 12 is a cross-sectional view schematically illustrating a structure in which a space between patterns of a first circuit layer and an empty space in a first opening is filled with an insulating material by pressing an upper portion of a second metal layer and an upper portion of a via conductor and a lower portion of a first insulating layer using a molding auxiliary material.

FIG. 13 is a cross-sectional view schematically illustrating a structure of a printed circuit board according to a first embodiment of the present disclosure, in which a via land is disposed by plating the second opening of FIG. 12, and a second metal layer is patterned to forma second circuit layer.

FIG. 14 is a cross-sectional view schematically illustrating a printed circuit board according to a second embodiment of the present disclosure.

FIGS. 15 and 16 are cross-sectional views schematically illustrating structures of the printed circuit boards of FIGS. 13 and 14, respectively, as third and fourth embodiments, which is manufactured by a double-sided build-up method instead of a single-sided build-up method.

### DETAILED DESCRIPTION

Hereinafter, the present disclosure will be described with reference to the accompanying drawings. In the drawings, shapes and sizes of elements may be exaggerated or reduced for clarity.

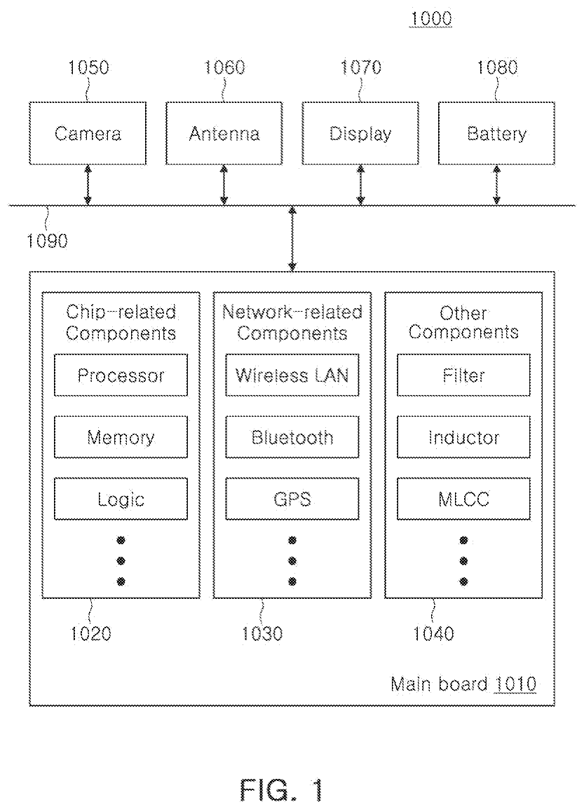

FIG. 1 is a block diagram schematically illustrating an example of an electronic device system.

Referring to the drawings, an electronic device 1000 may accommodate a main board 1010 therein. The main board 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. In addition, the chip related components 1020 may be combined with each other. The chip related component 1020 may be in the form of a package including the above-described chip.

The network related components 1030 may include protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with the chip related components 1020, and may be provided in a package form.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with the chip related components 1020 and/or the network related components 1030, and may be provided in package form.

Depending on a type of the electronic device 1000, the electronic device 1000 may include other components that may or may not be physically and/or electrically connected to the main board 1010. These other components may include, for example, a camera module 1050, an antenna module 1060, a display device 1070, a battery 1080, or the like. However, these other components are not limited thereto, but may also include an audio codec, a video codec, a power amplifier, a compass, an accelerometer, a gyroscope, a speaker, amass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

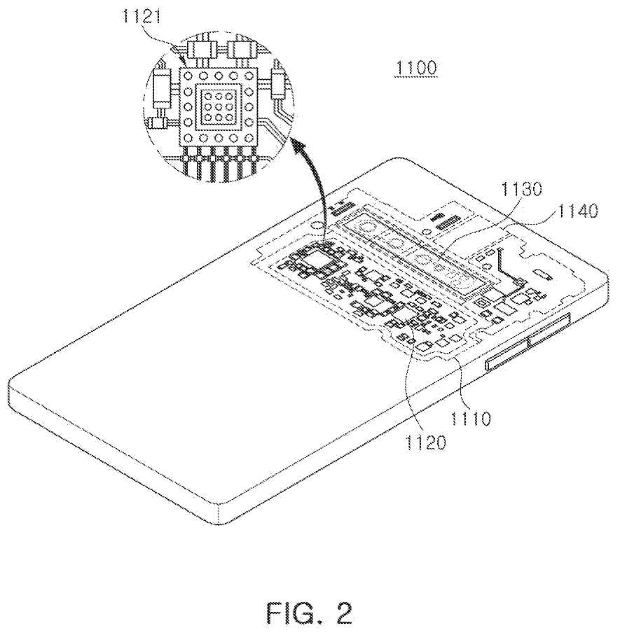

FIG. 2 is a plan view schematically illustrating an example of an electronic device.

Referring to FIG. 2, an electronic device may be, for example, a smartphone 1100. A mainboard 1110 may be accommodated in the smartphone 1100, and various electronic components 1120 may be physically or electrically connected to the mainboard 1110. In addition, other electronic components that may or may not be physically or electrically connected to the mainboard 1110, such as a camera module 1130 and/or a speaker 1140, may be accommodated therein. Some of the electronic components 1120 may be the chip related components, for example, a semiconductor package 1121, but are not limited thereto. The semiconductor package 1121 may have a form in which a semiconductor chip or a passive component is surface-mounted on a package substrate of a multilayer printed circuit board, but an embodiment thereof is not limited thereto. On the other hand, the electronic device is not necessarily limited to the smartphone 1100, and may be another electronic device as described above.

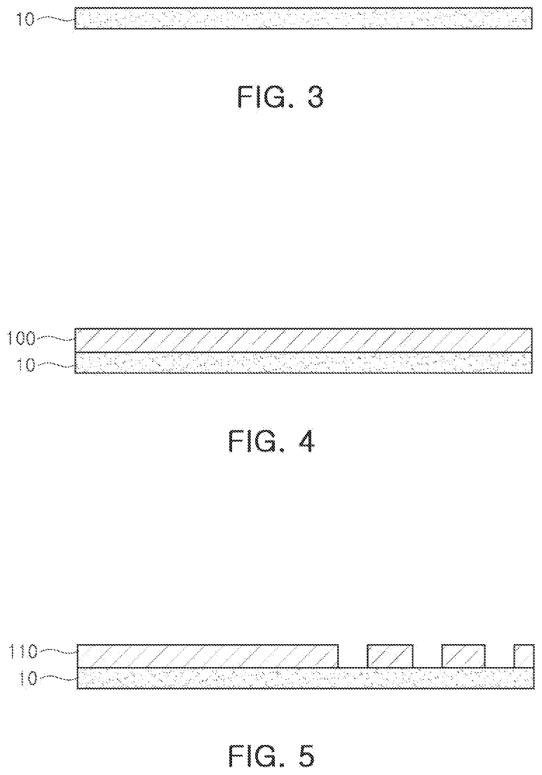

FIG. 3 is a cross-sectional view schematically illustrating a first insulating layer.

To manufacture a printed circuit board 500A according to a first embodiment, a first insulating layer 10 disclosed in FIG. 3 may be prepared. The first insulating layer 10 is not particularly limited as long as it may be an insulating resin that may be generally used as an insulating material in a printed circuit board, and as the insulating material, a thermosetting resin such as an epoxy resin, a thermoplastic resin such as polyimide, or resins in which reinforcements such as glass fiber and/or inorganic fillers are impregnated into these, may be used. For example, a resin such as prepreg, Ajinomoto Build-up Film (ABF), FR-4, bismaleimide triazine (BT) and the like may be used.

FIG. 4 is a cross-sectional view schematically illustrating a structure in which a first metal layer is stacked on one surface of a first insulating layer.

A first metal layer 100 may be stacked on one surface of the first insulating layer 10. The first metal layer 100 may include a metal material, and any metal material having excellent electrical conductivity is not particularly limited. Examples of the metal material may include copper (Cu), aluminum (Al), silver (Ag), tin (Sn), gold (Au), nickel (Ni), lead (Pb), titanium (Ti), alloys thereof, or the like.

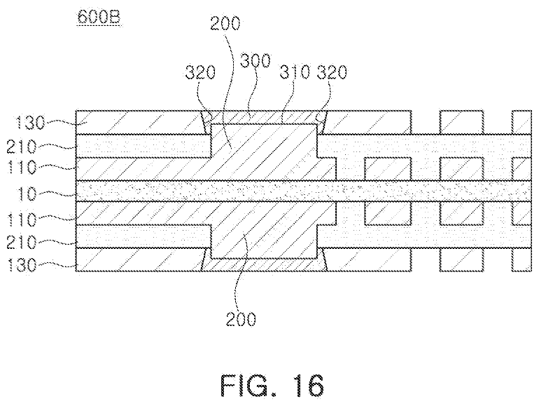

The first metal layer 100 or an insulating layer may be built up on the one surface of the first insulating layer 10, and the build-up structure to be described below may be applied equally to a lower surface of the first insulating layer 10 as well as an upper surface of the first insulating layer 10, to be applied to both of the upper and lower surfaces. Thus, finally, printed circuit boards 600A (shown in FIG. 15) and 600B (shown in FIG. 16) having a structure built-up on both of the surfaces may be manufactured.

FIG. 5 is a cross-sectional view schematically illustrating a structure in which a first circuit layer is formed by patterning a first metal layer.

As disclosed in FIG. 5, the first metal layer 100 may be patterned to forma first circuit layer 110. The first circuit layer 110 may be formed by an additive process (AP), a semi-AP (SAP), a modified SAP (MSAP), a tenting (TT) process, or the like, and as a result, may include a seed layer, which may be electroless plating layers, and an electrolytic plating layer formed on the basis of the seed layer, respectively. The first circuit layer 110 may perform various functions, depending on a design of the corresponding layer. For example, the first circuit layer 110 may include a feed pattern. In addition, the first circuit layer 110 may include a ground pattern, a power pattern, a signal pattern, and the like. Each of these patterns may include a line pattern, a plane pattern, and/or a pad pattern.

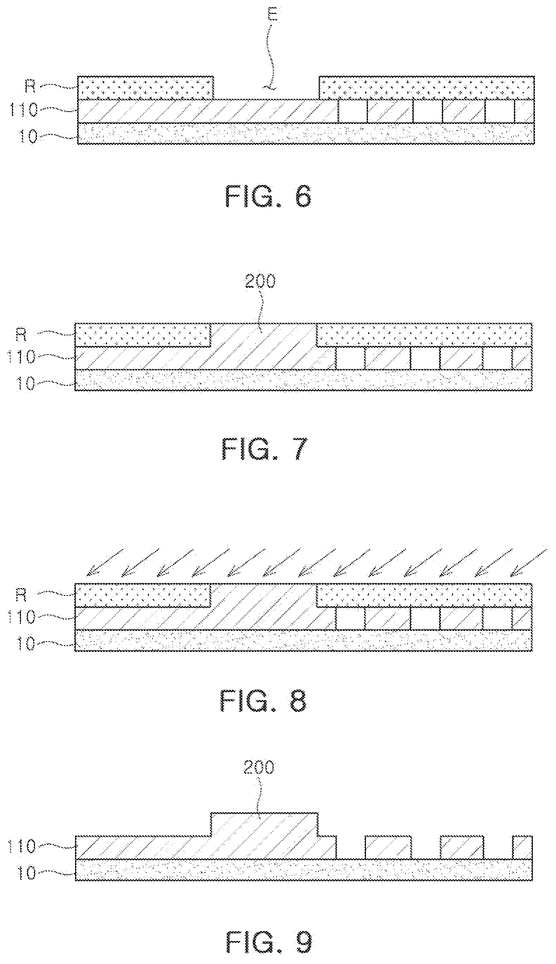

FIG. 6 is a cross-sectional view schematically illustrating a structure in which a dry film is stacked on a first circuit layer.

As disclosed in FIG. 6, a dry film R (e.g., a dry film resist (DFR)) may be stacked on the first circuit layer 110, to have an exposed portion E exposing at least a portion of the first circuit layer 110. For convenience, the dry film R may be named and described in the present disclosure. In this case, the dry film R may be used without limitations thereon, as long as the dry film R is used as an auxiliary material for forming a plating resist.

FIG. 7 is a cross-sectional view schematically illustrating a structure in which a via conductor is plated on an exposed region of a first circuit layer.

As disclosed in FIG. 7, a via conductor 200 may be disposed on the exposed portion E on the first circuit layer 110 exposed by the dry film R, by a plating process. The via conductor 200 may include a metal material. As the metal material, copper (Cu), aluminum (Al), silver (Ag), tin (Sn), gold (Au), nickel (Ni), lead (Pb), titanium (Ti), alloys thereof, or the like may be used. The via conductor 200 may be formed by the same plating process as the first circuit layer 110, or may be formed by other plating processes. The via conductor 200 may perform various functions, depending on a design. For example, the via conductor 200 may include a feed via conductor for connection of a feed pattern, a signal via conductor for connection of a signal pattern, a ground via conductor for connection of a ground pattern, a power via conductor for connection of a power pattern, and the like. Each of these via conductors may be completely filled with a metal material, or a metal material may be formed along a wall surface of the exposed portion E.

In general, in a case of a via hole formed by a physical process including laser drilling or CNC drilling, a lateral surface of the via hole may have a tapered shape. Thereafter, the tapered via hole may be filled with a metal material therein to form a conventional via conductor.

In a case of a method of manufacturing a printed circuit board according to the present disclosure, the process of forming the via hole by drilling may be eliminated, to improve process efficiency, shorten the process time, and improve productivity of the printed circuit board. After forming the exposed portion E with the dry film R, instead of the via hole formed by drilling, the exposed portion E may be plated with a metal material to form the via conductor 200. As a result, the via conductor 200 manufactured by such a manufacturing method may have a relatively straight shape, rather than a tapered side. In other words, the via conductor 200 may not have a structure in which a width or diameter of a cross-section of the via conductor 200 decreases in a downward direction, and may have a structure in which the width or diameter of the cross-section is substantially maintained to be the same in the downward direction.

Therefore, the via conductor 200 of the printed circuit board manufactured according to the manufacturing method presented in the present disclosure may be further improved in terms of reliability and a matching characteristic.

In addition, when a via hole is formed in an insulating material such as prepreg (PPG) by laser drilling, insulating material powder particles such as prepreg resin residues or the like in the insulating layer may be generated, to reduce reliability of the via. As another effect according to the present disclosure, because the exposed portion E may not be formed by laser processing, but may be formed by arrangement of the dry film R, the present disclosure may prevent the generation of the above-described residues of the insulating material. As a result, the reliability and a matching characteristic of the via conductor 200 may be improved.

FIG. 8 is a cross-sectional view schematically illustrating a process of polishing or etching an upper surface of a via conductor and an upper surface of a dry film.

As disclosed in FIG. 8, after plating of the via conductor 200 disposed on the exposed portion E is completed, an upper surface of the via conductor 200 may not be smooth, but may have roughness. Therefore, a semi-etching or polishing process may be performed to prevent the above. The roughness formed on the via conductor 200 may be eliminated to be flattened by the process. Therefore, the via conductor 200 and a via land 300 to be described later may be easier to be connected to each other, when the via land 300 is plated.

FIG. 9 is a cross-sectional view schematically illustrating a structure off of which a dry film is peeled.

As described above, the via conductor 200 may be formed by plating on the exposed portion E formed by the dry film R, and may be electrically connected to the first circuit layer 110. Since the via conductor 200 may be formed by the dry film R, a lateral surface of the via conductor 200 may have a substantially straight shape, e.g., a cross-sectional area, a width, or a diameter of the via conductor 200 is substantially maintained to be the same in the downward direction.

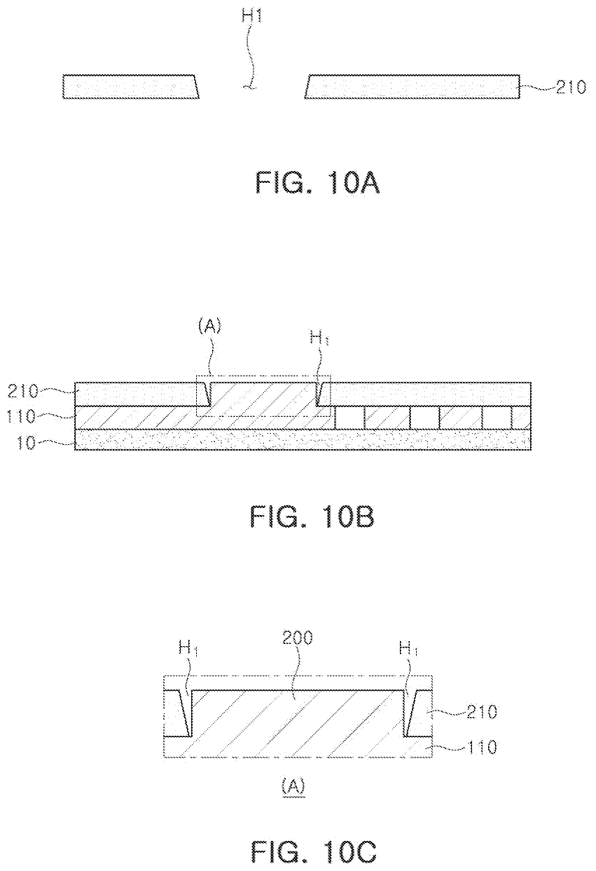

FIG. 10A is a cross-sectional view schematically illustrating a structure in which a first opening is formed in a second insulating layer before stacking.

FIG. 10A illustrates a cross-sectional view of a second insulating layer 210 prepared in advance to be stacked on the first circuit layer 110. The second insulating layer 210 is not particularly limited, as long as it is made of an insulating material that may be typically used as an insulating material on a printed circuit board, and may be advantageous for a thermosetting resin such as epoxy resin, a thermoplastic resin such as polyimide, or resins in which reinforcements such as glass fiber and/or inorganic fillers are impregnated into these, may be used. For example, the second insulating layer 210 may be formed of a resin such as prepreg, Ajinomoto Build-up Film (ABF), FR-4, bismaleimide triazine (BT) and the like.

Regarding a thickness of the second insulating layer 210, when considering an arrangement relationship between the second insulating layer 210, the first circuit layer 110, and the via conductor 200, the thickness of the second insulating layer 210 may be equal to or less than a thickness of the via conductor 200.

In this case, in the second insulating layer 210 according to the present disclosure, a first opening H1 may be processed in one region. The first opening H1 may be processed to at least partially overlap the exposed portion E on which the via conductor 200 is disposed, to at least partially overlap the via conductor 200. Therefore, the first opening H1 may be processed in a position in which at least one region of the via conductor 200 is exposed, when stacking is performed on the second insulating layer 210.

In addition, the first opening H1 may be processed in a position, corresponding to the via conductor 200, in consideration of a case in which the second insulating layer 210 is stacked on the first circuit layer 120, and a cross-sectional area or a width of the first opening H1 may be processed to be greater than a cross-sectional area or a width of the via conductor 200. This is to make a cross-sectional area of the first opening H1 of the second insulating layer 210 greater than a cross-sectional area of the via conductor 200 to form an excess space between the via conductor 200 and the first opening H1 after stacking, to match the via conductor 200 and the second insulating layer 210 during stacking. Detailed structures after stacking may be illustrated in FIGS. 10B and 10C.

The first opening H1 may be processed by a method of processing a conventional via hole, for example, laser drilling, and thus may have a shape tapered in the downward direction.

FIG. 10B is a cross-sectional view schematically illustrating a structure in which a second insulating layer is stacked on a first circuit layer, and FIG. 10C is an enlarged cross-sectional view enlarging and illustrating portion A of FIG. 10B.

As disclosed in FIG. 10B, the second insulating layer 210 may be stacked on the first circuit layer 210. The second insulating layer 210 may have a structure covering at least a portion of the first circuit layer 210. As described above, in the second insulating layer 210, the first opening H1 having a greater cross-sectional area than the via conductor 200 may be processed in a position corresponding to the via conductor 200. As disclosed in FIG. 10B, a space of the first opening H1 may still exist between the via conductor 200 and the second insulating layer 210 after stacking.

The first opening H1 of the second insulating layer 210 may be processed by a processing method such as laser drilling, and may have a tapered shape. As illustrated in detail in FIG. 10C, a lateral surface of the first opening H1 and a lateral surface of the via conductor 200 may be arranged to oppose each other, while having an angle of inclination from the lateral surface of the via conductor 200 formed to have a straight shape.

In addition, as described above, a thickness of the second insulating layer 210 may be equal to or less than a thickness of the via conductor 200. Therefore, when an upper surface of the via conductor 200 is disposed on the same plane as an upper surface of the second insulating layer 210, or when the thickness of the via conductor 200 is greater than the thickness of the second insulating layer 210, the upper surface of the via conductor 200 may be formed in a position higher than the upper surface of the second insulating layer 210, to be arranged to form a step difference between the upper surfaces.

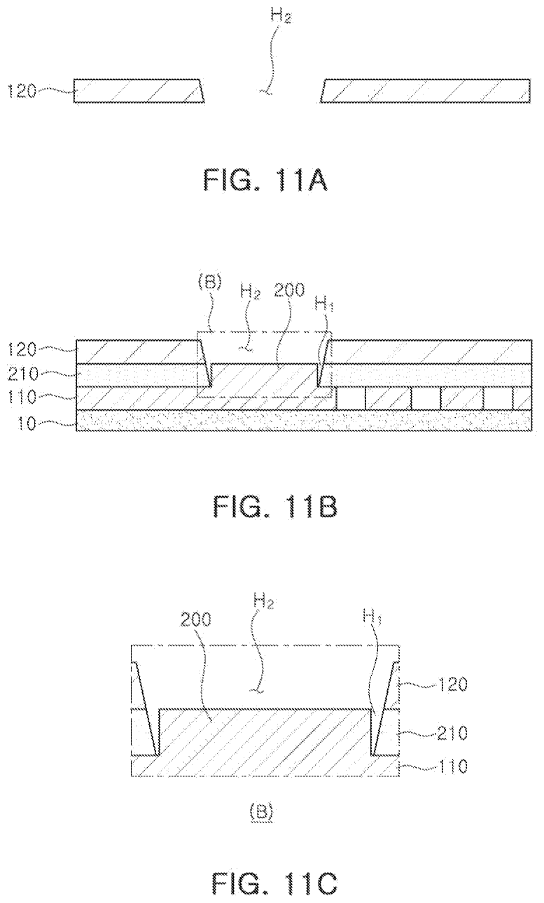

FIG. 11A is a cross-sectional view schematically illustrating a structure in which a second opening is formed in a second metal layer before stacking.

A second metal layer 120 may include a metal material. As the metal material, copper (Cu), aluminum (Al), silver (Ag), tin (Sn), gold (Au), nickel (Ni), lead (Pb), titanium (Ti), alloys thereof, or the like, may be used, and the same material as the first circuit layer 110 may be included.

In a manner similar to the case of the second insulating layer 210, in the second metal layer 120, a second opening H2 may be processed in advance before stacking, and the second opening H2 may be processed by a method of processing a conventional via hole, for example, laser drilling, and thus may have a shape tapered in the downward direction.

The second opening H2 may be processed in a position in which at least a portion of the second circuit layer 120 overlaps the first opening H1, for example, corresponding to the first opening H1.

FIG. 11B is a cross-sectional view schematically illustrating a structure in which a second metal layer is stacked on a second insulating layer, and FIG. 11C is an enlarged cross-sectional view enlarging and illustrating portion B of FIG. 11B.

As disclosed in FIG. 11B, the second metal layer 120 may be stacked on the second insulating layer 210. As described above, the second opening H2 may be processed in the second metal layer 120, and as disclosed in FIG. 11B, the second opening H2 may be processed to correspond to a position in which the first opening H1 is processed. Therefore, even after the second metal layer 120 having the second opening H2 is stacked on the second insulating layer 210, the first opening H1 and an upper surface of the via conductor 200 may be still exposed toward the second opening H2. Although not disclosed in the drawings, a position of the second opening H2 is not necessarily limited to being processed in a position corresponding to the first opening H1.

Subsequently, an enlarged cross-sectional view of FIG. 11C schematically illustrates an arrangement relationship between the second insulating layer 210 and the first and second openings H1 and H2 of the second metal layer 120 arranged thereon. As illustrated, lateral surfaces of the first and second openings H1 and H2 may be processed at the same angle, a cross-sectional areas of the first and second openings H1 and H2 in an interface therebetween may be identical, and the lateral surfaces of the first and second openings H1 and H2 may be located on the same plane, but are not necessarily limited thereto. For example, when the second opening H2 overlaps at least a portion of the first opening H1, angles of the lateral surfaces of the first and second openings H1 and H2 may be different from each other, and an upper cross-sectional area of the first opening H1 may not match a lower cross-sectional area of the second opening H2.

Similarly, when the upper surface of the second insulating layer 210 and the upper surface of the via conductor 200 are located on the same plane, it may be obvious that an interface between the second metal layer 120 and the second insulating layer 210 may be also coplanar with the upper surface of the via conductor 200.

In addition, when the thickness of the via conductor 200 is greater than the thickness of the second insulating layer 210, the upper surface of the second insulating layer 210 may be disposed to be lower than the upper surface of the via conductor 200, to form a step difference between the upper surfaces, and an interface between the second metal layer 120 and the second insulating layer 210 may be disposed to be lower than the upper surface of the via conductor 200.

When the second metal layer 120 is formed on the second insulating layer 210, the upper surface of the second metal layer 120 may be disposed to be higher than the upper surface of the via conductor 200, to initiate a structure having a step difference therebetween.

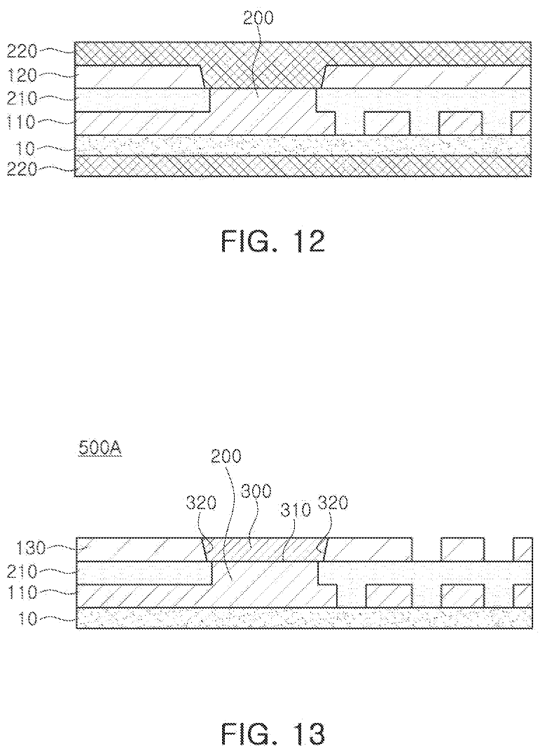

FIG. 12 is a cross-sectional view schematically illustrating a process of pressing an upper portion of a second metal layer and an upper portion of a via conductor using a molding auxiliary material.

A molding subsidiary material 220 may have a shape corresponding to a step difference between the upper surface of the second metal layer 120 and the upper surface of the via conductor 200. Therefore, the molding subsidiary material 220 may be made of a material of which shape may be controlled to match the shape of the step difference, for example, a material including polyvinyl chloride (PVC), and may be used without limitations to any material as long as the material is filled therein to match the shape of the second opening H2.

The molding subsidiary material 220 formed to correspond to a step difference between the upper surface of the second metal layer 120 and the upper surface of the via conductor 200 may be compressed by heating and pressing the upper surface of the second metal layer 120 and the upper surface of the via conductor 200 from the top. When using a double-sided build-up method, the upper surface of the second metal layer 120 and the upper surface of the via conductor 200 may be heated and pressed from the top and from the bottom.

As disclosed in FIG. 12, during heating and pressing, an insulating material, such as a resin of a prepreg (PPG) that may be included in the second insulating layer 210, may be melted by heating, to have fluidity. The insulating material having fluidity may fill the second opening H1, remaining as an excess space between the second insulating layer 210 and the via conductor 200, to insulate the via conductor 200 and improve stability.

In addition, the insulating material having fluidity may flow into and be filled in an empty space between the circuit patterns of the first circuit layer 110, as disclosed in FIG. 12. In this case, the second insulating layer 210 having fluidity and filling between the first circuit layers 110 may contact the first insulating layer 10.

FIG. 13 is a cross-sectional view schematically illustrating a structure of a printed circuit board according to a first embodiment of the present disclosure, in which a via land is disposed by plating the second opening of FIG. 12, and a second metal layer is patterned to forma second circuit layer.

As described above, the first opening H1 between the via conductor 200 and the insulating material 210 may be filled with the insulating material 210 having fluidity. Thereafter, a via land 300 may be formed on an exposed surface of the via conductor 200, e.g., on the second opening H2 by plating, to form a printed circuit board 500A.

As a result, the via land 300 may have the same shape as the second opening H2. As described above, a cross-sectional area or a width of the via land 300 may be greater than a cross-sectional area or a width of the via conductor 200. In addition, similar to the shape of the second opening H2, the via land 300 may have a tapered shape. Therefore, a second interface 320 may be formed to have a greater angle of inclination, as compared to a lateral surface of the via conductor 200 having a straight shape in which a cross-sectional area is substantially the same.

While the via conductor 200 and the via land 300 may be in electrical contact and may be connected, a first interface 310 may be formed on the contact surface between the via conductor 200 and the via land 300. The first interface 310 may be prepared by forming the via conductor 200 first, and forming the via land 300 plated later and disposed to cover the top of the via conductor 200, in sequence, and states of the interfaces may be grasped when fracture analyzing a final structure thereof.

A second circuit layer 130 may be prepared as disclosed in FIG. 13 by patterning the second metal layer 120. As described above, the second circuit layer 130 may be formed by stacking and then patterning on the second insulating layer 210. As disclosed in FIG. 11A, the second circuit layer 130 may be patterned in advance before stacking, and may then be stacked on the insulating layer 210.

In a manner similar to the printed circuit board 500A according to the first embodiment disclosed in FIG. 13, the first interface 310 may be disposed on the same plane as the upper surface of the second insulating layer 210, and thus, the first interface 310 may be coplanar with the upper surface of the second insulating layer 210.

Since the upper surface of the via conductor 200 may be formed to be lower than an upper surface of the second circuit layer 130, the first interface 310 and an upper surface of the second metal layer 120 may have a structure having a step difference therebetween.

In addition, in a manner different from the first interface 310, the via land 300 may form the second interface 320 in a region contacting the second circuit layer 130. In this case, the second interface 320 may have an inclined structure, in a manner similar to a lateral surface of the second opening H2 of the second circuit layer 130, and may be formed to have a constant angle of inclination in the thickness direction. In the present disclosure, the thickness direction means the same direction as the stacking direction of the printed circuit board. The inclined structure may be derived, when processing the second opening H2 in the second metal layer 120, since the second opening H2 may have a tapered shape due to a processing method such as laser drilling.

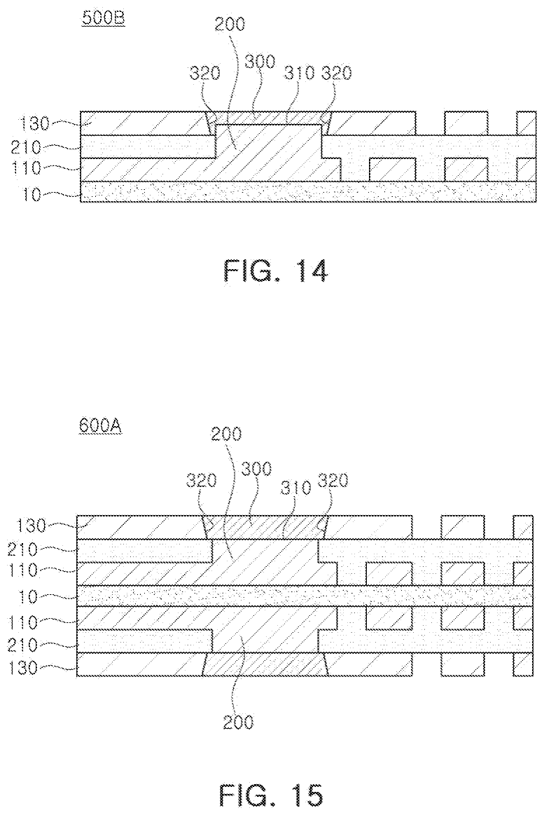

FIG. 14 is a cross-sectional view schematically illustrating another second embodiment 500B of a printed circuit board.

A printed circuit board 500B according to the second embodiment disclosed in FIG. 14 may correspond to a finally obtained structure, when the second insulating layer 210 of FIG. 10B is stacked, and a thickness of the second insulating layer 210 is less than a thickness of the via conductor 200.

As in the case of the first embodiment disclosed in FIG. 13, when the via land 300 is formed by plating, the first interface 310 may be formed on a contact surface between the via conductor 200 and the via land 300 by sequentially plating the via conductor 200 and the via land 300. As in the second embodiment of FIG. 14, the via land 300 may cover not only the upper surface of the via conductor 200, but also a partial area of the lateral surface of the via conductor 200, and the first interface 310 may be formed in at least a portion of each of the upper and lateral surfaces of the via conductor 200.

The printed circuit board 500B disclosed in FIG. 14 may be a structure derived when a thickness of the via conductor 200 is greater than a thickness of the second insulating layer 210. In this case, the first interface 310 may be located in a position higher than the upper surface of the second insulating layer 210, and the first interface 310 and the upper surface of the second insulating layer 210 may have a structure having a step difference. The first interface 310 may be formed in a position lower than the upper surface of the second circuit layer 130, and the upper surfaces of the first interface 310 and the second circuit layer 130 may also have a structure having a step difference.

In addition, the second interface 320 may be formed on a contact surface between the second circuit layer 130 and the via land 300 by sequentially plating the second circuit layer 130 and the via land 300. In this case, the second interface 320 is. As disclosed in FIG. 14, the second circuit layer 130 may have an inclined shape along a lateral surface of the second opening H2.

Other details may be substantially the same as those of the printed circuit board 500A according to the first embodiment described above, and detailed descriptions of overlapping contents will be omitted.

FIGS. 15 and 16 are cross-sectional views schematically illustrating structures of the printed circuit boards of FIGS. 13 and 14, respectively, as third and fourth embodiments, manufactured using a double-sided build-up method instead of a single-sided build-up method.

FIG. 15 illustrates a case in which the printed circuit board 500A of FIG. 13 is manufactured by a double-sided build-up method (600A), and FIG. 16 illustrates a case in which the printed circuit board 500B of FIG. 14 is manufactured by a double-sided build-up method (600B). Other contents may be substantially the same as each of the printed circuit boards 500A and 500B according to the above-described embodiments, except for a difference between the single-sided built-up case and the double-sided built-up case. Detailed descriptions of overlapping contents will be omitted.

In the present disclosure, for convenience, expressions such as a lateral portion, a lateral surface, and the like may be used to refer to a x or y direction or a surface in the direction, expressions such as an upper side, an upper portion, an upper surface, and the like may be used to refer to a z direction or a surface in the direction, and expressions such as a lower side, a lower portion, a lower surface, and the like may be used to refer to a direction, opposing the z direction, or a surface in the direction. In addition, positioning at the lateral portion, the upper side, the upper portion, the lower side, or the lower portion may be used as a concept including not only that a component is in direct contact with a reference component in a corresponding direction, but also that a component is positioned in the corresponding direction but is not in direct contact with the reference component. However, for convenience of explanation, the above expressions have been defined based on a direction, and the scope of the claims is not particularly limited by the description of this direction, and the upper/lower concepts may be changed at any time.

The term of “connect” or “connection” in the present disclosure may be not only a direct connection, but also a concept including an indirect connection through an adhesive layer or the like. In addition, the term “electrically connected” or “electrical connection” in the present disclosure is a concept including both a physical connection and a physical non-connection. Also, the expressions of “first,” second,” etc. in the present disclosure are used to distinguish one component from another, and do not limit the order and/or importance of the components. In some cases, without departing from the spirit of the present disclosure, a first component may be referred to as a second component, and similarly, a second component may be referred to as a first component.

The expression “example”, except in relation to experimental examples, used in this specification does not refer to the same embodiment to each other, but may be provided for emphasizing and explaining different unique features. However, the above-mentioned examples do not exclude that the above-mentioned examples are implemented in combination with the features of other examples. For example, although the description in a specific example is not described in another example, it can be understood as an explanation related to another example, unless otherwise described or contradicted by the other example.

The terms used in the present disclosure are used only to illustrate various examples and are not intended to limit the present inventive concept. Singular expressions include plural expressions unless the context clearly dictates otherwise.

As one of the effects of the present disclosure, a printed circuit board having excellent reliability and a matching characteristic of a via may be provided.

As another effect of the various effects of the present disclosure, a printed circuit board having a structure in which an interface is formed between a via conductor and a via land to distinguish the via conductor and the via land may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a first circuit layer disposed on one surface of the first insulating layer;
a second insulating layer disposed on the first insulating layer and covering at least a portion of the first circuit layer;
a via conductor passing through the second insulating layer and connected to the first circuit layer;
a via land connected to the via conductor in an upper portion of the via conductor; and
a second circuit layer disposed on the second insulating layer and connected to the via land,
wherein the via conductor and the via land have a first interface where the via conductor and the via land are in contact with each other.

2. The printed circuit board of claim 1, further comprising a third circuit layer disposed on the other surface of the first insulating layer.

3. The printed circuit board of claim 1, wherein the via land is disposed in a position in which at least a portion of the via conductor overlaps with the via land.

4. The printed circuit board of claim 1, wherein the via conductor has substantially the same cross-sectional area in a stacking direction of the first insulating layer and the first circuit layer.

5. The printed circuit board of claim 4, wherein the via land has a tapered shape.

6. The printed circuit board of claim 4, wherein the second circuit layer and the via land have a second interface where the second circuit layer and the via land are in contact with each other.

7. The printed circuit board of claim 6, wherein the second interface has a relatively large slope, compared to a lateral surface of the via conductor, in a thickness direction.

8. The printed circuit board of claim 5, wherein a width of the via land is greater than a width of the via conductor.

9. The printed circuit board of claim 8, wherein the first interface is coplanar with an upper surface of the second insulating layer.

10. The printed circuit board of claim 8, wherein a thickness of the via conductor is greater than a thickness of a portion of the second insulating layer disposed on the first circuit layer.

11. The printed circuit board of claim 8, wherein the first interface is disposed on at least a portion of an upper surface and at least a portion of a lateral surface of the via conductor.

12. The printed circuit board of claim 8, wherein the via land is in contact with at least a portion of a lateral surface of the via conductor.

13. A printed circuit board comprising:
a first insulating layer;
a first circuit layer disposed on at least portion of one surface of the first insulating layer;
a second insulating layer disposed on at least portion of the one surface of the first insulating layer and covering at least a portion of the first circuit layer;
a via conductor passing through the second insulating layer and connected to the first circuit layer;
a via land connected to the via conductor in an upper portion of the via conductor; and
a second circuit layer disposed on the second insulating layer and connected to the via land,
wherein the via land and the second circuit layer have a second interface where the via land and the second circuit layer are in contact with each other.

14. The printed circuit board of claim 13, wherein an upper surface and a lower surface of the via conductor have substantially the same cross-sectional area.

15. The printed circuit board of claim 14, wherein an upper surface and a lower surface of the via land have different cross-sectional areas.

16. The printed circuit board of claim 15, wherein the via conductor and the via land have a first interface where the via conductor and the via land are in contact with each other.

17. A printed circuit board comprising:
a first insulating layer;
a first circuit layer disposed on the first insulating layer and having an opening;
a second insulating layer disposed on the first circuit layer and extending in the opening of the first circuit layer to contact the first insulating layer;
a via conductor passing through a portion of the second insulating layer disposed on the first circuit layer, and connected to the first circuit layer; and
a second circuit layer disposed on the second insulating layer and connected to the via conductor.

18. The printed circuit board of claim 17, further comprising a via land connecting the via conductor and the second circuit layer to each other.

19. The printed circuit board of claim 18, wherein an upper surface and a lower surface of the via land have different cross-sectional areas.

20. The printed circuit board of claim 17, wherein an upper surface and a lower surface of the via conductor have substantially the same cross-sectional area.

21. A method for manufacturing a printed circuit board, the method comprising:
forming a first circuit layer on a first insulating layer;
after forming the first circuit layer, forming a via conductor extending from the first circuit layer;
disposing a second insulating layer with an opening on the first circuit layer such that the via conductor is disposed in the opening in the second insulating layer; and
forming a second circuit layer on the second insulating layer.

22. The method of claim 21, further comprising forming a via land in an opening in the second circuit layer to connect the via conductor and the second circuit layer to each other.

23. The method of claim 21, further comprising heating and pressing the second insulating layer such that a material of the second insulating layer moves to a space of the opening to contact the via conductor.
